(19) United States
(12) Patent Application Publication
(10) Pub. No.: US 2025/0234527 A1
(43) Pub. Date: Jul. 17, 2025

(54) SEMICONDUCTOR DEVICE

(71) Applicant: Samsung Electronics Co., Ltd., Suwon-si (KR)

(72) Inventors: Jeon Il LEE, Suwon-si (KR); Juho LEE, Suwon-si (KR); Kyunghwan LEE, Suwon-si (KR); Sanghoon UHM, Suwon-si (KR)

(73) Assignee: Samsung Electronics Co., Ltd., Suwon-si (KR)

(21) Appl. No.: 18/765,633

(22) Filed: Jul. 8, 2024

(30) Foreign Application Priority Data
Jan. 16, 2024 (KR) 10-2024-0006981

(51) Int. Cl. H10B 12/00

(52) U.S. Cl. CPC H10B 12/488; H10B 12/315; H10B 12/482

(57) ABSTRACT

The present disclosure relates to a semiconductor device including a substrate, a bit line extending in a vertical direction, the vertical direction being perpendicular to an upper surface of the substrate, semiconductor patterns having first ends connected to the bit line and spaced apart in the vertical direction, a pair of word lines above and below respective semiconductor patterns, and data storage patterns connected to second ends of respective semiconductor patterns. Each of the semiconductor patterns include a first portion connected to the bit line and including polysilicon, a second portion connected to each of the data storage patterns and including an oxide semiconductor material, and a third portion between the first portion and the second portion and including a metal silicide material.

### CROSS-REFERENCE TO RELATED APPLICATION

This application claims priority to and the benefit of Korean Patent Application No. 10-2024-0006981 filed in the Korean Intellectual Property Office on Jan. 16, 2024, the entire contents of which are incorporated herein by reference.

### BACKGROUND

Various example embodiments of the present disclosure relate to a semiconductor device.

Technology to increase integration of semiconductor devices is required. In the case of two-dimensional (2D) semiconductor devices, integration is mainly determined by the area occupied by a unit memory cell, and integration in this aspect may depend on levels of fine pattern formation technology.

However, the fine pattern formation technology requires expensive equipment, so although integration of the 2D semiconductor devices is increasing, it is still limited. Accordingly, 3D semiconductor memory devices having memory cells arranged in the 3D are being proposed.

### SUMMARY

Various example embodiments provide a semiconductor device for increasing electrical reliability of channels and reducing a leakage current to improve operation characteristics.

Various example embodiments of the present disclosure provide a semiconductor device including a substrate, a bit line extending in a vertical direction, the vertical direction being perpendicular to an upper surface of the substrate, semiconductor patterns having first ends connected to the bit line and spaced apart in the vertical direction, a pair of word lines above and below respective semiconductor patterns, and data storage patterns connected to second ends of respective semiconductor patterns. Each of the semiconductor patterns include a first portion connected to the bit line and including polysilicon, a second portion connected to each of the data storage patterns and including an oxide semiconductor material, and a third portion between the first portion and the second portion and including a metal silicide material.

Various example embodiments of the present disclosure provide a semiconductor device including a substrate, a bit line extending in a vertical direction, the vertical direction being perpendicular to an upper surface of the substrate, semiconductor patterns having a first end connected to the bit line and spaced apart in the vertical direction, a pair of word lines above and below respective semiconductor patterns and extending in a first direction, the first direction being parallel to the upper surface the substrate, and data storage patterns connected to second ends of respective semiconductor patterns. Each of the semiconductor patterns include a first portion connected to the bit line and including polysilicon, a second portion connected to the data storage pattern and including an oxide semiconductor material, and a third portion between the first portion and the second portion and including a metal silicide material, and an interface between the second portion and the third portion is between facing surfaces of the pair of word lines.

Other various example embodiments of the present disclosure provide a semiconductor device including a substrate, a bit line extending in a vertical direction, the vertical direction being perpendicular to an upper surface of the substrate, semiconductor patterns having first ends connected to the bit line and spaced apart in the vertical direction, a pair of word lines above and below respective semiconductor patterns and extending in a first direction that is parallel to the upper surface of the substrate, and data storage patterns connected to second ends of respective semiconductor patterns. Each of the semiconductor patterns include a first portion connected to the bit line and including polysilicon, a second portion connected to the data storage pattern and including an oxide semiconductor material, and a third portion between the first portion and the second portion and including a metal silicide material, and the first portion, the third portion, and the second portion are sequentially arranged in a second direction between the bit line and the data storage pattern, the second direction being parallel to the upper surface of the substrate and perpendicular to the first direction.

According to various example embodiments, the electrical reliability of the channel may be increased, and the leakage current may be reduced, thereby improving the operation characteristic of the semiconductor device.

According to various example embodiments, contact resistance among the portions of the channels including different materials may be reduced.

### BRIEF DESCRIPTION OF THE DRAWINGS

FIG. 1 shows a perspective view of a semiconductor device according to various example embodiments.

FIG. 2 shows a cross-sectional view of a semiconductor device according to various example embodiments.

FIG. 3 shows a cross-sectional view of a semiconductor device according to various example embodiments.

FIG. 4 shows a cross-sectional view of a semiconductor device according to various example embodiments.

FIG. 5 to FIG. 15 show cross-sectional views on a method for manufacturing a semiconductor device according to various example embodiments.

### DETAILED DESCRIPTION

In the following detailed description, only certain example embodiments of the present disclosure have been shown and described, simply by way of illustration. As those skilled in the art would realize, the described example embodiments may be modified in various different ways, all without departing from the spirit or scope of the present disclosure.

Parts that are irrelevant to the description will be omitted to clearly describe the various example embodiments, and the same elements will be designated by the same reference numerals throughout the specification.

The size and thickness of each configuration shown in the drawings are arbitrarily shown for better understanding and ease of description, but various example embodiments are not limited thereto. The thickness of layers, films, panels, regions, etc., are enlarged for clarity. For ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. It will be understood that when an element such as a layer, film, region, or substrate is referred to as being “on” another element, it can be directly on the other element or intervening elements may also be present.

Unless explicitly described to the contrary, the word “comprise,” and variations such as “comprises” or “comprising,” will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

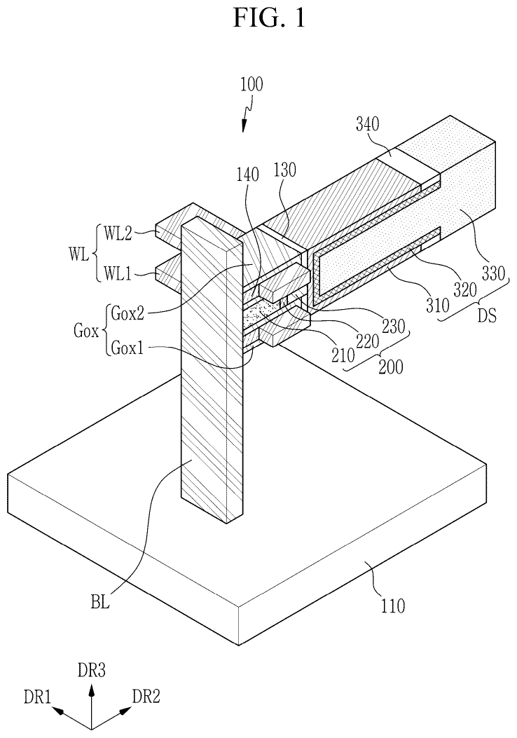

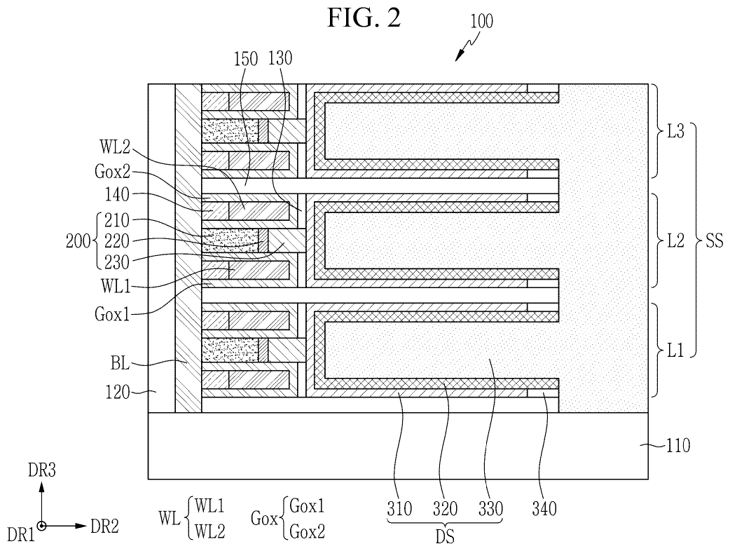

A semiconductor device according to various example embodiments will now be described with reference to FIG. 1 and FIG. 2.

FIG. 1 shows a perspective view of a semiconductor device according to various example embodiments. FIG. 2 shows a cross-sectional view of a semiconductor device according to various example embodiments.

The semiconductor device 100 may include 3-dimensionally arranged memory cells. The memory cells may be arranged in a first direction DR1, a second direction DR2, and a third direction DR3. The first direction DR1 and the second direction DR2 may be parallel to the upper surface of the substrate 110. For example, the second direction DR2 may be perpendicular to the first direction DR1. The third direction DR3 may be perpendicular to the upper surface of the substrate 110. The memory cells may be stacked in the third direction DR3. Each memory cell may be connected to one bit line BL and two word lines WL.

The bit line BL may extend in the third direction DR3. The memory cells stacked in the third direction DR3 may be connected in common to the bit line BL. The bit lines BL may be arranged in the first direction DR1. The bit lines BL may be arranged in the second direction DR2.

The word line WL may extend in the first direction DR1. The memory cells arranged in the first direction DR1 may be connected in common to the word line WL. The word lines WL may be arranged in the third direction DR3. Each memory cell may be connected to the two adjacent word lines WL arranged in the third direction DR3. The word lines WL may be arranged in the second direction DR2.

FIG. 1 shows a memory cell and one bit line BL and two word lines WL connected to the memory cell, and other memory cells are omitted for ease of description. FIG. 1 shows a cell of a layer of a stacking structure body SS shown in FIG. 2.

FIG. 2 shows three memory cells connected in common to one bit line BL and stacked in the third direction DR3. FIG. 2 further shows memory cells arranged in the third direction DR3 which are omitted in FIG. 1. FIG. 2 shows that the stacking structure body SS includes three layers, which is not limited thereto. According to various example embodiments, the stacking structure body SS may include a greater number of layers. FIG. 2 shows that each layer of the stacking structure body SS includes one memory cell, which is not limited thereto. According to various example embodiments, each layer of the stacking structure body SS may include a greater number of cells. For example, each layer of the stacking structure body SS may further include a memory cell that is mirror symmetric to the structure of the memory cell shown in FIG. 2. For example, a stacking structure body that is mirror symmetric to the stacking structure body SS of FIG. 2 in the second direction DR2 may be further provided on the substrate 110. The stacking structure body SS and the stacking structure body that is mirrored symmetrically to the stacking structure body SS may make a pair. The one pair of stacking structure bodies may share a second electrode 330 of data storage patterns DS to be described.

Referring to FIG. 1 and FIG. 2, the semiconductor device 100 may include a substrate 110, a bit line BL extending in the third direction DR3 that is vertical to the substrate 110, semiconductor patterns 200 connected to the bit line BL, a pair of word lines WL disposed above/below the respective semiconductor patterns 200, and a data storage pattern DS connected to the respective semiconductor patterns. According to various example embodiments, first ends of the respective semiconductor patterns 200 may be connected to the bit line BL, and second ends may be connected to the data storage pattern DS.

According to various example embodiments, the stacking structure body SS may be provided on the substrate 110. The substrate 110 may, for example, be a silicon substrate, a germanium substrate, or a silicon-germanium substrate. However, example embodiments are not limited thereto. The stacking structure body SS may configure a memory cell array of the semiconductor device. Although not shown, a peripheral circuit for operating the memory cell array may be provided on the substrate 110. Wires electrically connected to the bit lines BL and the word lines WL may be provided on the stacking structure body SS, and may be connected to the peripheral circuit.

A bit line BL and a first interlayer insulating layer 120 may be provided on a side of the stacking structure body SS. The bit line BL may extend in the third direction DR3. The bit line BL may have a linear form or a column form extending in the third direction DR3.

The bit line BL may be electrically connected to a semiconductor pattern 200. The bit line BL may contact the semiconductor pattern 200.

The bit line BL may include a conductive material. The conductive material may be one of, for example, a doped semiconductor material such as doped silicon or doped germanium, a conductive metal nitride such as titanium nitride or tantalum nitride, a metal such as tungsten, titanium, or tantalum, and a metal-semiconductor compound such as tungsten silicide, cobalt silicide, or titanium silicide. However, example embodiments are not limited thereto.

The first interlayer insulating layer 120 may extend in the third direction DR3. The first interlayer insulating layer 120 may extend in the first direction DR1. The first interlayer insulating layer 120 may cover the bit line BL. The first interlayer insulating layer 120 may extend into a space among the bit lines BL arranged in the first direction DR1. By the first interlayer insulating layer 120, the bit lines BL arranged in the first direction DR1 may be insulated from each other.

The first interlayer insulating layer 120 may include, for example, at least one of a silicon nitride layer, a silicon oxide nitride layer, a carbon-contained silicon oxide, a carbon-contained silicon nitride layer, or a carbon-contained silicon oxynitride layer. However, example embodiments are not limited thereto.

The stacking structure body SS may include layers. For example, the stacking structure body SS may include a first layer L1, a second layer L2, and a third layer L3 sequentially stacked on the substrate 110. The first layer L1, the second layer L2, and the third layer L3 may be stacked in the third direction DR3. The first layer L1, the second layer L2, and the third layer L3 may respectively include a semiconductor pattern 200, a pair of word lines WL disposed above/below the semiconductor pattern 200, and a data storage pattern DS connected to the semiconductor pattern 200.

Second interlayer insulating layers 150 may be disposed between two layers that are adjacent each other. The second interlayer insulating layers 150 may be disposed between the first layer L1 and the second layer L2 and may be disposed between the second layer L2 and the third layer L3. The word lines WL, the semiconductor pattern 200, and the data storage pattern DS on the respective layers may be provided on the second interlayer insulating layer 150. The word lines WL disposed on the upper layer and the word lines WL disposed on the lower layer may be spaced in the third direction DR3 by the second interlayer insulating layer 150. The semiconductor pattern 200 on the upper layer and the semiconductor pattern 200 on the lower layer may be spaced in the third direction DR3 by the second interlayer insulating layer 150. The data storage pattern DS on the upper layer and the data storage pattern DS on the lower layer may be spaced in the third direction DR3 by the second interlayer insulating layer 150.

The second interlayer insulating layer 150 may be disposed between a lowermost layer of the stacking structure body SS and the substrate 110.

The second interlayer insulating layer 150 may include, for example, at least one of a silicon nitride layer, a silicon oxynitride layer, a carbon-contained silicon oxide, a carbon-contained silicon nitride layer, and a carbon-contained silicon oxynitride layer. However, example embodiments are not limited thereto.

The word line WL may extend in the first direction DR1. The word line WL may have a linear form extending in the first direction DR1. Each layer may include two word lines WL. The first word line WL1 and the second word line WL2 may be spaced from each other in the third direction DR3 on each layer. For example, the first word line WL1 may be disposed nearer the substrate 110 than the second word line WL2 is.

The word line WL may include a conductive material. For example, the conductive material may be one of a semiconductor material, a conductive metal nitride, a metal, and a metal-semiconductor compound. However, example embodiments are not limited thereto.

A spacer 140 may be disposed between the word line WL and the bit line BL. The spacer 140 may include an insulating material, and may insulate the bit line BL and the word line WL.

A gate insulating layer Gox may surround exposed surfaces of the word line WL and the spacer 140. The gate insulating layer Gox may conformally cover the word line WL and the spacer 140. The gate insulating layer Gox may cover an upper surface, a lateral surface, and a bottom surface of the word line WL. The gate insulating layer Gox may cover an upper surface and a bottom surface of the spacer 140.

The gate insulating layer Gox may contact the bit line BL. A portion of the gate insulating layer Gox covering the upper surface of the spacer 140 and the upper surface of the word line WL and a portion of the gate insulating layer Gox covering the bottom surface of the spacer 140 and the bottom surface of the word line WL may contact the bit line BL.

The gate insulating layer Gox may include at least one of a high dielectric layer, a silicon oxide, a silicon nitride layer, and a silicon oxynitride layer. The high dielectric layer may, for example, include at least one of a hafnium oxide, a hafnium silicon oxide, a lanthanum oxide, a zirconium oxide, a zirconium silicon oxide, a tantalum oxide, a titanium oxide, a barium strontium titanium oxide, a barium titanium oxide, a strontium titanium oxide, a lithium oxide, an aluminum oxide, a lead scandium tantalum oxide, or a lead zinc niobate. However, example embodiments are not limited thereto.

The gate insulating layer Gox may include a first gate insulating layer Gox1 disposed between the first word line WL1 and the semiconductor pattern 200 and a second gate insulating layer Gox2 disposed between the second word line WL2 and the semiconductor pattern 200. The semiconductor pattern 200 may be spaced from the first word line WL1 by the first gate insulating layer Gox1. The semiconductor pattern 200 may be spaced from the second word line WL2 by the second gate insulating layer Gox2. The first gate insulating layer Gox1 may surround the first word line WL1 and the spacer 140 disposed between the first word line WL1 and the bit line BL. The second gate insulating layer Gox2 may surround the second word line WL2 and the spacer 140 disposed between the second word line WL2 and the bit line BL. The first gate insulating layer Gox1 and the second gate insulating layer Gox2 may respectively contact the bit line BL.

According to various example embodiments, the semiconductor pattern 200 may be disposed between one pair of word lines WL on each layer. The semiconductor pattern 200 may be disposed between the first word line WL1 and the second word line WL2. The semiconductor pattern 200 may be disposed between the first gate insulating layer Gox1 and the second gate insulating layer Gox2. A first end of the semiconductor pattern 200 may be connected to the bit line BL. A second end of the semiconductor pattern 200 may be connected to the data storage pattern DS. The semiconductor pattern 200 may be disposed in the space surrounded by the upper surface of the first gate insulating layer Gox1, the bottom surface of the second gate insulating layer Gox2, and the lateral surface of the bit line BL.

According to various example embodiments, the semiconductor pattern 200 may include a first portion 210 connected to the bit line BL, a second portion 230 connected to the data storage pattern DS, and a third portion 220 disposed between the first portion 210 and the second portion 230. The first portion 210 may include polysilicon. The second portion 230 may include an oxide semiconductor material. As a portion of the semiconductor pattern 200 contacted by the data storage pattern DS includes an oxide semiconductor material and not polysilicon, a gate induced drain leakage (GIDL) current may be reduced.

According to various example embodiments, the oxide semiconductor material included by the second portion 230 may include a material that has a high composition ratio of indium. The oxide semiconductor material may include a plurality of materials including indium, and the composition ratio of indium among the plurality of materials may be high. For example, a high composition ratio of indium may mean that when the oxide semiconductor material includes indium and material A, indium/(indium+A) is greater than A/(indium+A). When the composition ratio of indium increases, contact resistance of the semiconductor pattern 200 and the data storage pattern DS may be improved. For example, the oxide semiconductor material included by the second portion 230 may include an indium gallium zinc oxide (IGZO), an In₂O₃, an indium tin oxide (ITO), an indium gallium oxide (IGO), and an indium tin gallium oxide (ITGO), but example embodiments are not limited thereto.

According to various example embodiments, the third portion 220 may include a metal silicide material. The metal silicide material included by the third portion 220 may be, for example, a titanium silicide (TiSi₂), a cobalt silicide (CoSi₂), a nickel silicide (NiSi₂), a hafnium silicide (HfSi₂), a molybdenum silicide (MoSi₂), or a tungsten silicide (WSi₂). However, example embodiments are not limited thereto.

According to various example embodiments, the first portion 210, the third portion 220, and the second portion 230 may be sequentially arranged in the second direction DR2 between the bit line BL and the data storage pattern DS. According to what is described above, the first portion 210 may be connected to the bit line BL, and the second portion 230 may be connected to the data storage pattern DS. The first portion 210 and the second portion 230 may be spaced in the second direction DR2 by the third portion 220. One of surfaces of the first portion 210 facing each other in the second direction DR2 may contact the bit line BL, and the other may contact the third portion 220. One of surfaces of the second portion 230 facing each other in the second direction DR2 may contact the data storage pattern DS, and the other may contact the third portion 220. The first portion 210 including polysilicon is spaced from the second portion 230 including an oxide semiconductor material, thereby limiting and/or preventing a silicon oxide from being generated on an interface between the first portion 210 and the second portion 230. Limiting and/or preventing a silicon oxide from being generated at this interface may prevent an increase in the resistance of the semiconductor pattern 200.

According to various example embodiments, a region of the first portion 210 disposed near the third portion 220 may include n-type impurities. The n-type impurities may be doped in the region of the first portion 210 contacting the third portion 220. The n-type impurities may include, for example, phosphorus (P) or arsenic (As). However, example embodiments are not limited thereto.

According to various example embodiments, at least a portion of the semiconductor pattern 200 may overlap one pair of word lines WL in the third direction DR3. At least a portion of the second portion 230 of the semiconductor pattern 200 may overlap the first word line WL1 and the second word line WL2 in the third direction DR3. An entire portion of the third portion 220 of the semiconductor pattern 200 may overlap the first word line WL1 and the second word line WL2 in the third direction DR3.

According to various example embodiments, a portion of the second portion 230 may be disposed between the first word line WL1 and the second word line WL2, and another portion of the second portion 230 may protrude in accordance with a distance from the bit line BL between a lateral surface of the first word line WL1 and a lateral surface of the second word line WL2. A portion of the second portion 230 may contact the third portion 220, and another portion of the second portion 230 may contact the data storage pattern DS. In this case, a portion of the second portion 230 disposed near the third portion 220 may overlap the first word line WL1 and the second word line WL2 in the third direction DR3.

According to several example embodiments, the second portion 230 may be disposed between the first word line WL1 and the second word line WL2. In this case, an entire portion of the second portion 230 may overlap the first word line WL1 and the second word line WL2 in the third direction DR3.

According to various example embodiments, a portion of the first portion 210 of the semiconductor pattern 200 may overlap the first word line WL1 and the second word line WL2 in the third direction DR3. For example, a portion of the first portion 210 may be disposed between the first word line WL1 and the second word line WL2, and another portion of the first portion 210 may protrude toward the bit line BL between the lateral surface of the first word line WL1 and the lateral surface of the second word line WL2. The other portion of the first portion 210 may be disposed between the spacer 140 disposed between the first word line WL1 and the bit line BL and the spacer 140 disposed between the second word line WL2 and the bit line BL. A portion of the first portion 210 may contact the bit line BL, and another portion of the first portion 210 may contact the third portion 220. In this case, a portion of the first portion 210 disposed near the third portion 220 may overlap the first word line WL1 and the second word line WL2 in the third direction DR3.

According to various example embodiments, a length of the first portion 210 in the second direction DR2, overlapping the first word line WL1 and the second word line WL2 may be greater than a length of the second portion 230 in the second direction DR2, overlapping the first word line WL1 and the second word line WL2. The first portion 210 including polysilicon further overlaps the word line WL than the second portion 230 including an oxide semiconductor material does, thereby increasing electrical reliability of the semiconductor pattern 200.

According to various example embodiments, the interface of the second portion 230 and the third portion 220 of the semiconductor pattern 200 may be disposed between extending lines of surfaces of the word lines WL facing each other in the second direction DR2. The third portion 220 of the semiconductor pattern 200 may be disposed between the extending lines of the surfaces of the word lines WL facing each other in the second direction DR2. For example, the first word line WL1 may include a first surface and a second surface facing each other in the second direction DR2, and the second word line WL2 may include a third surface and a fourth surface facing each other in the second direction DR2. The first surface and the third surface may be disposed in a line in the third direction DR3, and the second surface and the fourth surface may be disposed in a line in the third direction DR3. The interface of the second portion 230 and the third portion 220 may be disposed between the extending line of the first surface and the third surface and the extending line of the second surface and the fourth surface. The interface of the first portion 210 and the third portion 220 may be disposed between the extending line of the first surface and the third surface and the extending line of the second surface and the fourth surface.

According to various example embodiments, the interface of the second portion 230 and the data storage pattern DS may be more distant from the bit line BL than the surfaces of the word lines WL facing each other in the second direction DR2. The interface of the second portion 230 and the data storage pattern DS may, for example, be distant from the bit line BL than the second surface and the fourth surface. In this case, a portion of the second portion 230 may overlap the word line WL in the third direction DR3.

According to several example embodiments, the interface of the second portion 230 and the data storage pattern DS may be disposed nearer the bit line BL than the surfaces of the word lines WL facing each other in the second direction DR2. The interface of the second portion 230 and the data storage pattern DS may, for example, be disposed near the bit line BL than the second surface and the fourth surface. In this case, an entire portion of the second portion 230 may overlap the word line WL in the third direction DR3.

An etch stopping layer 130 may be disposed on one side of one pair of word lines WL. The etch stopping layer 130 may be disposed on one sides of the first word line WL1 and the second word line WL2. The etch stopping layer 130 may be disposed on lateral surfaces of the first gate insulating layer Gox1 and the second gate insulating layer Gox2. The etch stopping layer 130 may be disposed on a lateral surface of the first gate insulating layer Gox1 covering the lateral surface of the first word line WL1. The etch stopping layer 130 may be disposed on a lateral surface of the second gate insulating layer Gox2 covering the lateral surface of the second word line WL2. The etch stopping layer 130 may include a portion disposed on the lateral surface of the first gate insulating layer Gox1 and a portion disposed on the lateral surface of the second gate insulating layer Gox2. The etch stopping layer 130 may include portions separated in the third direction DR3.

According to various example embodiments, at least a portion of the second portion 230 of the semiconductor pattern 200 may be disposed between a portion of the etch stopping layer 130 disposed on the lateral surface of the first gate insulating layer Gox1 and a portion of the etch stopping layer 130 disposed on the lateral surface of the second gate insulating layer Gox2. At least a portion of the second portion 230 may overlap portions of the etch stopping layer 130 disposed on the lateral surfaces of the first gate insulating layer Gox1 and the second gate insulating layer Gox2 in the third direction DR3.

According to various example embodiments, the interface of the second portion 230 of the semiconductor pattern 200 and the data storage pattern DS may be disposed between the portion of the etch stopping layer 130 disposed on the lateral surface of the first gate insulating layer Gox1 and the portion of the etch stopping layer 130 disposed on the lateral surface of the second gate insulating layer Gox2.

The etch stopping layer 130 may contact the data storage pattern DS. According to various example embodiments, the interface of the second portion 230 of the semiconductor pattern 200 and the data storage pattern DS and the interface of the etch stopping layer 130 and the data storage pattern DS may be disposed in a line, but are not limited thereto. According to several example embodiments, the interface of the second portion 230 and the data storage pattern DS may be disposed nearer the bit line BL than the interface of the etch stopping layer 130 and the data storage pattern DS. In this case, a portion of the data storage pattern DS may protrude toward the bit line BL and may be disposed between the portions of the etch stopping layer 130 disposed on the respective lateral surfaces of the first gate insulating layer Gox1 and the second gate insulating layer Gox2.

The etch stopping layer 130 may include, for example, a material that has etch selectivity with a material of the second portion 230.

The data storage pattern DS may be electrically connected to the semiconductor pattern 200. The data storage pattern DS may be a memory component for storing data, for example, it may be a memory component using a capacitor, a memory component using a magnetic tunnel junction pattern, or a memory component using a variable resistor including a phase change material. However, example embodiments are not limited thereto.

According to various example embodiments, the data storage pattern DS may be a capacitor. According to various example embodiments, the data storage pattern DS may include a first electrode 310, a second electrode 330 spaced from the first electrode 310, and a dielectric layer 320 disposed between the first electrode 310 and the second electrode 330.

According to various example embodiments, the first electrode 310 may include a vertical portion extending in the third direction DR3 and a pair of horizontal portions extending in the second direction DR2. The vertical portion of the first electrode 310 may contact the second portion 230 of the semiconductor pattern 200 and the etch stopping layer 130. The vertical portion of the first electrode 310 may cover the lateral surface of the etch stopping layer 130 and the lateral surface of the second portion 230 and may extend in the third direction DR3. The horizontal portion of the first electrode 310 may extend in the second direction DR2 to be thus distant from the bit line BL from the vertical portion of the first electrode 310. One of the one pair of the horizontal portions of the first electrode 310 may extend in the second direction DR2 along the upper surface of the second interlayer insulating layer 150 disposed below each layer, and the other thereof may extend in the second direction DR2 along the bottom surface of the second interlayer insulating layer 150 disposed above each layer. The one pair of the horizontal portions of the first electrode 310 may be spaced in the third direction DR3. The first electrode 310 may have a cylindrical shape extending in the second direction DR2.

According to various example embodiments, the second electrode 330 may be inserted into the first electrode 310, and may be surrounded by the first electrode 310. The second electrode 330 may be inserted into an internal space of the first electrode 310 in a cylindrical shape. The second electrode 330 may penetrate layers and second interlayer insulating layers 150 and may be connected. The data storage patterns DS of the layers stacked in the third direction DR3 may share one second electrode 330. The second electrode 330 may include a vertical portion extending in the third direction DR3 and integrally formed on the layers of the stacking structure body SS, and a horizontal portion protruding in the second direction DR2 from the vertical portion and inserted into the first electrode 310.

The first electrode 310 and the second electrode 330 may include at least one of metallic materials such as titanium, tantalum, tungsten, copper, or aluminum, conductive metal nitrides such as a titanium nitride or a tantalum nitride, or doped semiconductor materials such as doped silicon or doped germanium. However, example embodiments are not limited thereto.

The dielectric layer 320 may be disposed between the first electrode 310 and the second electrode 330. The dielectric layer 320 may be conformally formed on the first electrode 310. The dielectric layer 320 may be disposed inside the first electrode 310, and may be surrounded by the first electrode 310. The dielectric layer 320 may have a similar shape to the first electrode 310. That is, the dielectric layer 320 may include a vertical portion extending in the third direction DR3 and a pair of horizontal portions extending in the second direction DR2. The vertical portion of the dielectric layer 320 may be disposed between the vertical portion of the first electrode 310 and the second electrode 330. The horizontal portion of the dielectric layer 320 may be disposed between the horizontal portion of the first electrode 310 and the second electrode 330. The dielectric layer 320 may include at least one of a dielectric material, a ferromagnetic material, or an antiferromagnetic material. The dielectric material may include a high dielectric constant material. For example, the dielectric material may include a hafnium oxide, a hafnium silicon oxide, a lanthanum oxide, a zirconium oxide, a zirconium silicon oxide, a tantalum oxide, a titanium oxide, a barium strontium titanium oxide, a barium titanium oxide, a strontium titanium oxide, a lithium oxide, an aluminum oxide, a lead scandium tantalum oxide, a lead zinc niobate, or combinations thereof. However, example embodiments are not limited thereto.

According to various example embodiments, an insulating pattern 340 may be disposed between the first electrode 310 and the second electrode 330. The insulating pattern 340 may be disposed between the horizontal portions of the first electrode 310 and the vertical portion of the second electrode 330. The insulating pattern 340 may be disposed between the dielectric layer 320 and the second interlayer insulating layer 150. That is, the insulating pattern 340 may be surrounded by the first electrode 310, the dielectric layer 320, the second electrode 330, and the second interlayer insulating layer 150. The first electrode 310 may be insulated from the second electrode 330 by the insulating pattern 340.

The insulating pattern 340 may, for example, include at least one of a silicon nitride, a silicon oxidation nitride, a carbon-contained silicon oxide, a carbon-contained silicon nitride, and a carbon-contained silicon oxidation nitride. However, example embodiments are not limited thereto.

According to various example embodiments, the first portion 210 of the semiconductor pattern 200 connected to the bit line BL may include polysilicon, and the second portion 230 of the semiconductor pattern 200 connected to the data storage pattern DS may include an oxide semiconductor material, thereby increasing electrical reliability of the semiconductor device 100 and reducing the gate induced drain leakage current (GIDL).

According to various example embodiments, the semiconductor pattern 200 may include a third portion 220 including a metal silicide material between the first portion 210 including polysilicon and the second portion 230 including an oxide semiconductor material, thereby limiting and/or preventing a silicon oxide from being formed on the interface of the first portion 210 and the second portion 230. Limiting and/or preventing a silicon oxide from being generated at this interface improve contact resistance of the semiconductor device 100.

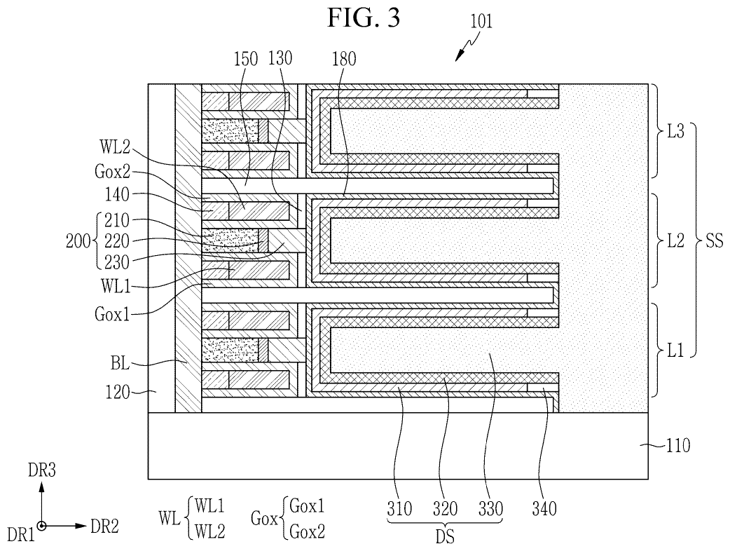

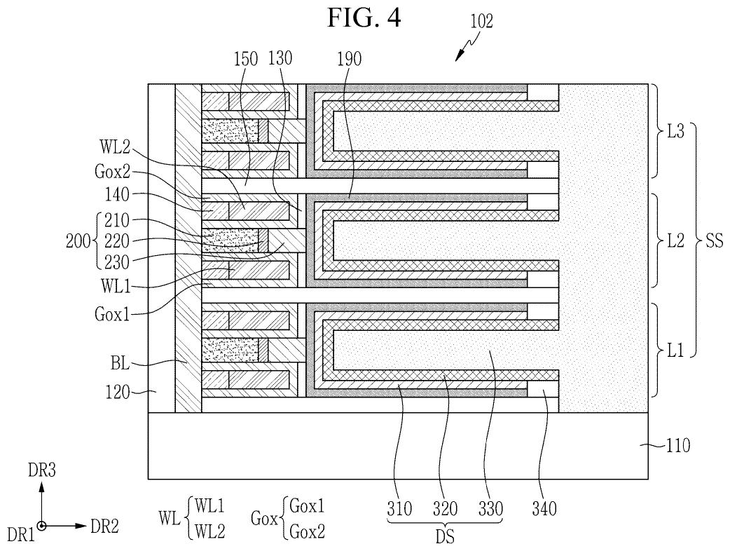

A semiconductor device according to various embodiments will now be described with reference to FIG. 3 and FIG. 4.

FIG. 3 shows a cross-sectional view of a semiconductor device according to various example embodiments. The semiconductor device 101 according to various example embodiments of FIG. 3 may have the same components except that an anti-oxidation layer 180 is added between the semiconductor pattern 200 of the semiconductor device 100 according to various example embodiments of FIG. 1 and

FIG. 2 and the data storage pattern DS. For convenience, differences will be mainly described, and the descriptions that overlap the above-noted descriptions given with reference to FIG. 1 and FIG. 2 will be omitted or simplified.

For example, the components included in the second layer L2 from among the layers of the stacking structure body SS will be described, which may be applied to other layers in an identical or similar way.

Referring to FIG. 3, the semiconductor device 101 may include an anti-oxidation layer 180 between the semiconductor pattern 200 and the data storage pattern DS. The anti-oxidation layer 180 may be disposed between the second portion 230 of the semiconductor pattern 200 including an oxide semiconductor material and the first electrode 310 of the data storage pattern DS. The first electrode 310 may not contact the second portion 230 by the anti-oxidation layer 180.

According to various example embodiments, the interface of the second portion 230 of the semiconductor pattern 200 and the anti-oxidation layer 180 and the interface of the etch stopping layer 130 and the anti-oxidation layer 180 may be arranged in a line, but are not limited thereto. According to several example embodiments, the interface of the second portion 230 and the anti-oxidation layer 180 may be disposed nearer the bit line BL than the interface of the etch stopping layer 130 and the anti-oxidation layer 180. In this case, a portion of the anti-oxidation layer 180 may protrude toward the bit line BL and may be disposed between portions of the etch stopping layer 130 disposed on respective lateral surfaces of the first gate insulating layer Gox1 and the second gate insulating layer Gox2.

According to various example embodiments, the anti-oxidation layer 180 may extend on the layers. The anti-oxidation layer 180 may conformally cover at least a portion of the respective second interlayer insulating layers 150 for separating the layers. The anti-oxidation layer 180 may conformally cover the second portion 230 of the semiconductor pattern 200 and the etch stopping layer 130. The anti-oxidation layer 180 covering the second portion 230 of the semiconductor pattern 200 of each layer and the etch stopping layer 130 may extend on the bottom surface of the second interlayer insulating layer 150 disposed above the layers and the upper surface of the second interlayer insulating layer 150 disposed below the layers. The anti-oxidation layer 180 may extend above the lateral surface of the second interlayer insulating layer 150 on the upper surface of the second interlayer insulating layer 150. The anti-oxidation layer 180 may extend above the bottom surface of the second interlayer insulating layer 150 on the lateral surface of the second interlayer insulating layer 150. The anti-oxidation layer 180 may extend above the lateral surface of the second interlayer insulating layer 150 on the bottom surface of the second interlayer insulating layer 150. The anti-oxidation layer 180 may extend above the upper surface of the second interlayer insulating layer 150 on the lateral surface of the second interlayer insulating layer 150.

According to various example embodiments, a portion of the anti-oxidation layer 180 covering the second portion 230 of the semiconductor pattern 200 and the etch stopping layer 130 and a portion of the anti-oxidation layer 180 covering the lateral surface of the second interlayer insulating layer 150 may extend in the third direction DR3. A portion of the anti-oxidation layer 180 covering the upper surface of the second interlayer insulating layer 150 and at least a portion of the bottom surface may extend in the second direction DR2.

The anti-oxidation layer 180 may, for example, include a silicon oxide, a silicon nitride, a silicon carbide, a silicon oxynitride, or a silicon carbonitride, but example embodiments are not limited thereto.

According to various example embodiments, a thickness of the anti-oxidation layer 180 may be equal to or less than about 1 nm. As the anti-oxidation layer 180 has the thickness, the second portion 230 of the semiconductor pattern 200 may be electrically connected to the first electrode 310.

According to various example embodiments, the anti-oxidation layer 180 is disposed between the second portion 230 of the semiconductor pattern 200 including an oxide semiconductor material and the first electrode 310 of the data storage pattern DS, thereby limiting and/or preventing the material of the first electrode 310 from being oxidized. Limiting and/or preventing oxidation at this interface may prevent an increase in the contact resistance.

FIG. 4 shows a cross-sectional view of a semiconductor device according to various example embodiments. The semiconductor device 102 according to various example embodiments of FIG. 4 has the same components as FIG. 1 and FIG. 2 except that a conductive layer 190 is added between the semiconductor pattern 200 and the data storage pattern DS of the semiconductor device 100, For convenience, differences will be mainly described, and the descriptions that overlap the above-noted descriptions given with reference to FIG. 1 and FIG. 2 will be omitted or simplified.

For example, the components included in the second layer L2 from among the layers of the stacking structure body SS will be described, which may be applied to other layers in an identical or similar way.

Referring to FIG. 4, the semiconductor device 101 may include a conductive layer 190 between the semiconductor pattern 200 and the data storage pattern DS. The conductive layer 190 may be disposed between the second portion 230 of the semiconductor pattern 200 including an oxide semiconductor material and the first electrode 310 of the data storage pattern DS.

The conductive layer 190 may include a conductive material. The conductive layer 190 may, for example, include metal nitrides such as a titanium nitride (TIN), a tungsten nitride (WN), or a tungsten carbonitride (WCN) or metallic materials such as cobalt (Co), but example embodiments are not limited thereto.

According to various example embodiments, the interface of the second portion 230 of the semiconductor pattern 200 and the conductive layer 190 and the interface of the etch stopping layer 130 and the conductive layer 190 may be disposed in a line, but are not limited thereto. According to several example embodiments, the interface of the second portion 230 and the conductive layer 190 may be disposed nearer the bit line BL than the interface of the etch stopping layer 130 and the conductive layer 190 is. In this case, a portion of the conductive layer 190 may protrude toward the bit line BL and may be disposed between the portions of the etch stopping layer 130 disposed on the respective lateral surfaces of the first gate insulating layer Gox1 and the second gate insulating layer Gox2.

According to various example embodiments, the conductive layer 190 may conformally cover at least portions of the second interlayer insulating layers 150 separating layers. The conductive layer 190 may conformally cover the second portion 230 of the semiconductor pattern 200 and the etch stopping layer 130. The conductive layer 190 covering the second portion 230 of the semiconductor pattern 200 of each layer and the etch stopping layer 130 may extend above the bottom surface of the second interlayer insulating layer 150 disposed above each layer and the upper surface of the second interlayer insulating layer 150 disposed below each layer.

According to various example embodiments, the conductive layer 190 may include a vertical portion extending in the third direction DR3 and a pair of horizontal portions extending in the second direction DR2. The second direction DR2 may be perpendicular to the first direction DR1 in which the word line WL extends. The vertical portion of the conductive layer 190 may cover the second portion 230 of the semiconductor pattern 200 and the etch stopping layer 130. The pair of horizontal portions of the conductive layer 190 may cover at least a portion of the upper surface and the bottom surface of the second interlayer insulating layer 150. The conductive layer 190 may surround the first electrode 310.

According to various example embodiments, the insulating pattern 340 may be disposed between the conductive layer 190 and the second electrode 330 and between the and first electrode 310 and the second electrode 330. The insulating pattern 340 may be disposed between the horizontal portions of the conductive layer 190 and a portion of the second electrode 330 extending in the third direction DR3. The insulating pattern 340 may be disposed between the horizontal portions of the first electrode 310 and the portion of the second electrode 330 extending in the third direction DR3. By the insulating pattern 340, the conductive layer 190 may be spaced from the second electrode 330, and the first electrode 310 may be spaced from the second electrode 330. The insulating pattern 340 may insulate the conductive layer 190 and the second electrode 330, and may insulate the first electrode 310 and the second electrode 330.

According to various example embodiments, the conductive layer 190 is disposed between the second portion 230 of the semiconductor pattern 200 including an oxide semiconductor material and the first electrode 310 of the data storage pattern DS, thereby reducing the contact resistance of the semiconductor pattern 200 and the data storage pattern DS.

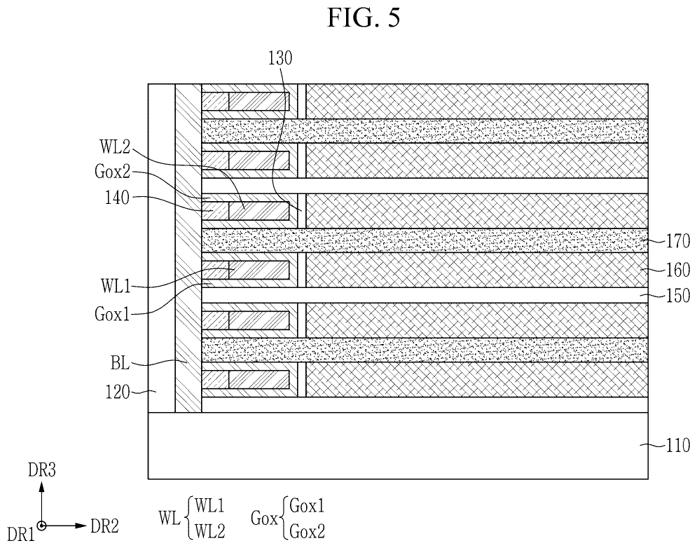

A method for manufacturing a semiconductor device according to various example embodiments will now be described with reference to FIG. 5 to FIG. 15. FIG. 5 to FIG. 15 show cross-sectional views on a method for manufacturing a semiconductor device according to various example embodiments. FIG. 5 to FIG. 15 shows a method for manufacturing a semiconductor device 100 according to various example embodiments of FIG. 1 and FIG. 2.

Referring to FIG. 5, the first interlayer insulating layer 120 extending in the third direction DR3 and the bit lines BL may be provided on the substrate 110. The bit lines BL may be spaced and disposed in the first direction DR1.

The bit line BL may include a conductive material. The conductive material may, for example, be one of doped semiconductor materials such as doped silicon or doped germanium, conductive metal nitrides such as a titanium nitride or a tantalum nitride, metals such as tungsten, titanium, or tantalum, or metal-semiconductor compounds such as a tungsten silicide, a cobalt silicide, or a titanium silicide. However, example embodiments are not limited thereto.

The first interlayer insulating layer 120 may extend in the first direction DR1. The first interlayer insulating layer 120 may extend to a space between the bit lines BL arranged in the first direction DR1 and may insulate the bit lines BL.

On one sides of the bit lines BL, the second interlayer insulating layer 150, the first sacrificial layer 160, and the first channel material layer 170 may be alternately stacked on the substrate 110. The second interlayer insulating layer 150, first sacrificial layer 160, and first channel material layer 170 may be alternately stacked in the third direction DR3. The second interlayer insulating layers 150 and the first channel material layers 170 may contact the bit lines BL. The first sacrificial layers 160 may be spaced in the second direction DR2 from the bit lines BL.

The first interlayer insulating layer 120 and the second interlayer insulating layer 150 may, for example, include at least one of a silicon nitride layer, a silicon oxynitride layer, a carbon-contained silicon oxide, carbon-contained silicon nitride layer, and a carbon-contained silicon oxynitride layer. However, example embodiments are not limited thereto. The first sacrificial layer 160 may, for example, include a silicon nitride.

According to various example embodiments, the first channel material layer 170 may include polysilicon.

The etch stopping layer 130 may be disposed on a surface that faces the bit lines BL of the first sacrificial layers 160. Portions of the etch stopping layer 130 may be spaced and disposed in the third direction DR3 by the second interlayer insulating layer 150 and the first channel material layer 170. The etch stopping layer 130 may, for example, include a material that has etch selectivity with the first sacrificial layer 160.

A gate insulating layer Gox may be provided in a space surrounded by the second interlayer insulating layer 150, the etch stopping layer 130, and the first channel material layer 170. The gate insulating layer Gox may include at least one of a high dielectric layer, a silicon oxide, a silicon nitride layer, and a silicon oxynitride layer. However, example embodiments are not limited thereto. The high dielectric layer may, for example, include at least one of a hafnium oxide, a hafnium silicon oxide, a lanthanum oxide, a zirconium oxide, a zirconium silicon oxide, a tantalum oxide, a titanium oxide, a barium strontium titanium oxide, a barium titanium oxide, a strontium titanium oxide, a lithium oxide, an aluminum oxide, a lead scandium tantalum oxide, or a lead zinc niobate. However, example embodiments are not limited thereto.

The first gate insulating layer Gox1 may conformally cover an upper surface of the second interlayer insulating layer 150, a bottom surface of the first channel material layer 170, and a lateral surface of the etch stopping layer 130 disposed between the second interlayer insulating layer 150 and the first channel material layer 170. One lateral surface of the etch stopping layer 130 may face the bit line BL.

The second gate insulating layer Gox2 may conformally cover an upper surface of the first channel material layer 170, an upper surface of the second interlayer insulating layer 150, and a lateral surface of the etch stopping layer 130 disposed between the first channel material layer 170 and the second interlayer insulating layer 150. One lateral surface of the etch stopping layer 130 may face the bit line BL.

A pair of word lines WL may be provided between the second interlayer insulating layers 150. The word lines WL may extend in the first direction DR1. The first direction DR1 and the second direction DR2 may be vertical to each other. A pair of word lines WL disposed between the second interlayer insulating layers 150 may include a first word line WL1 and a second word line WL2. The first word line WL1 and the second word line WL2 may be spaced and disposed in the third direction DR3. The first word line WL1 and second word line WL2 may be disposed above/below the semiconductor pattern 200. The first word line WL1 may be disposed nearer the substrate 110 than the second word line WL2 is.

The word line WL may include a conductive material. For example, the conductive material may be one of a semiconductor material, a conductive metal nitride, a metal, or metal-semiconductor compounds. However, example embodiments are not limited thereto.

The spacers 140 including an insulating material may be provided between the first word line WL1 and the bit line BL and between the second word line WL2 and the bit line BL. The spacers 140 may space the first word line WL1 and the second word line WL2 in the second direction DR2 from the bit line BL. The first word line WL1 and the second word line WL2 may be insulated from the bit line BL by the spacers 140.

The first word line WL1 and the spacer 140 disposed on the lateral surface of the bit line BL may be surrounded by the first gate insulating layer Gox1. The first gate insulating layer Gox1 may space the first word line WL1 from the first channel material layer 170. The second word line WL2 and the spacer 140 disposed on the lateral surface of the bit line BL may be surrounded by the second gate insulating layer Gox2. The second gate insulating layer Gox2 may space the second word line WL2 from the first channel material layer 170.

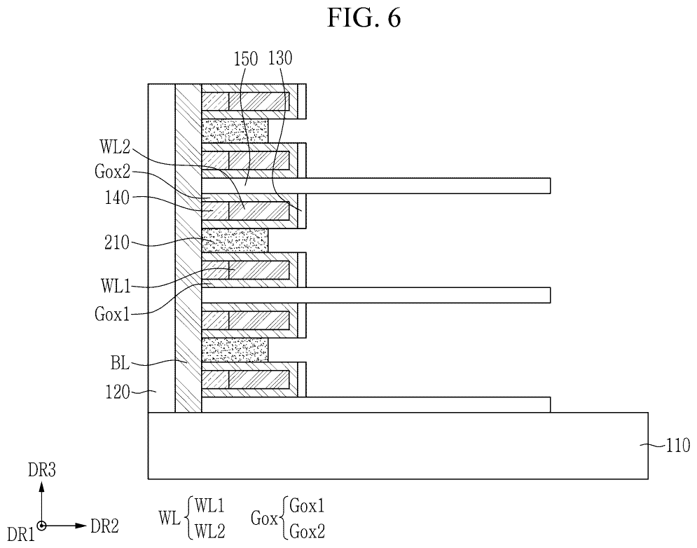

Referring to FIG. 6, a trench penetrating the second interlayer insulating layer 150, the first sacrificial layer 160, and the first channel material layer 170 in the third direction DR3 may be formed, and the first sacrificial layer 160 may be removed through the trench. For example, the first sacrificial layer 160 may be selectively etched by using an etchant that has high etch selectivity on the first sacrificial layer 160. By the etching process, the first sacrificial layer 160 may be removed and the etch stopping layer 130 may be exposed.

The first channel material layer 170 may be partly removed. For example, the first channel material layer 170 may be selectively etched by using an etchant that has high etch selectivity on the first channel material layer 170. By the etching process, the first channel material layer 170 may be partly removed and a first portion 210 may be formed. The first portion 210 includes the same material as the first channel material layer 170.

One of the surfaces of the first portion 210 facing each other in the second direction DR2 may contact the bit line BL, and another thereof may be disposed between the extending lines of the surfaces of the first word line WL1 and the second word line WL2 facing each other in the second direction DR2. For example, the first word line WL1 may include a first surface and a second surface facing each other in the second direction DR2, and the second word line WL2 may include a third surface and a fourth surface facing each other in the second direction DR2. A surface facing the surface contacting the bit line BL of the first portion 210 in the second direction DR2 may be disposed between the extending line of the first surface and the third surface and the extending line of the second surface and the fourth surface. According to various example embodiments, a portion of the first portion 210 may overlap the first word line WL1 and the second word line WL2 in the third direction DR3.

In the above-described example embodiments, the first sacrificial layer 160 and the first channel material layer 170 are etched by an additional process, but are not limited thereto. In several example embodiments, the first sacrificial layer 160 and the first channel material layer 170 may be etched together until the etch stopping layer 130 is exposed, and the first channel material layer 170 may then be additionally etched by another process.

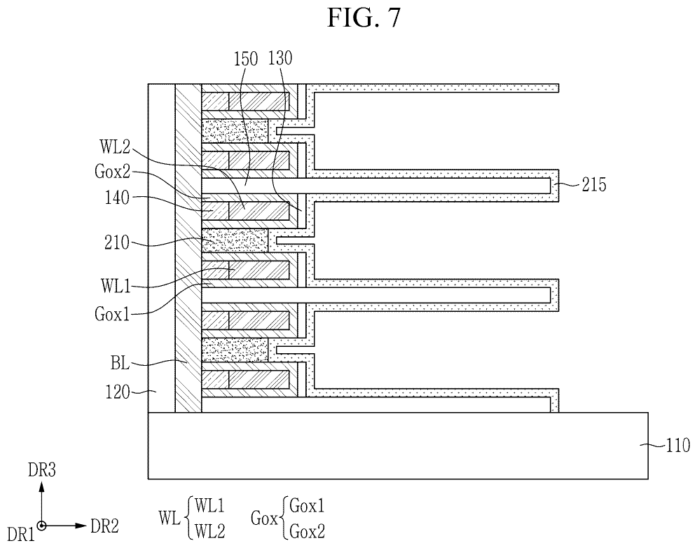

N-type impurities may be doped to a region disposed near the exposed surface of the first portion 210 before the process of FIG. 7 is performed. The n-type impurities may include, for example, phosphorus (P) or arsenic (As).

Referring to FIG. 7, a metal layer 215 may be formed. The metal layer 215 may include, for example, titanium, cobalt, nickel, hafnium, molybdenum, or tungsten. However, example embodiments are not limited thereto. For example, the metal layer 215 may be formed by a sputtering process, or a chemical vapor deposition process (CVD), however, example embodiments are not limited thereto, and the metal layer 215 may be deposited by various methods.

The metal layer 215 may conformally cover exposed surfaces of the second interlayer insulating layers 150, the etch stopping layer 130, the first gate insulating layers Gox1, the second gate insulating layers Gox2, and the first portions 210.

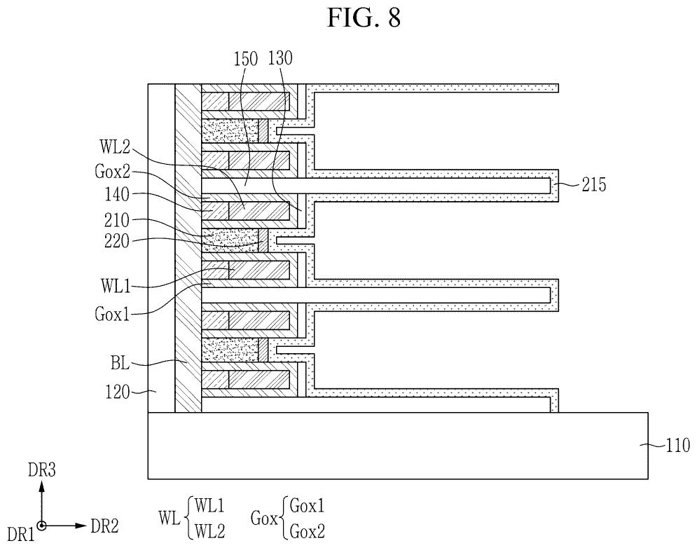

Referring to FIG. 8, by performing an annealing process, a portion of the first portion 210 contacting the metal layer 215 may be made into silicide to form a third portion 220. Hence, the third portion 220 contacting the metal layer 215 may include a metal silicide material. The metal silicide material may be, for example, titanium silicide (TiSi₂), cobalt silicide (CoSi₂), nickel silicide (NiSi₂), hafnium silicide (HfSi₂), molybdenum silicide (MoSi₂), or tungsten silicide (WSi₂) depending on a metallic material of the metal layer 215. However, example embodiments are not limited thereto.

The third portion 220 may be disposed between the extending lines of the surfaces of the first word line WL1 and the second word line WL2 facing each other in the second direction DR2. For example, the first word line WL1 may include a first surface and second surface facing each other in the second direction DR2, and the second word line WL2 may include a third surface and a fourth surface facing each other in the second direction DR2. The third portion 220 may be disposed between the extending line of the first surface and the third surface and the extending line of the second surface and the fourth surface.

According to various example embodiments, an entire portion of the third portion 220 may overlap the first word line WL1 and the second word line WL2 in the third direction DR3.

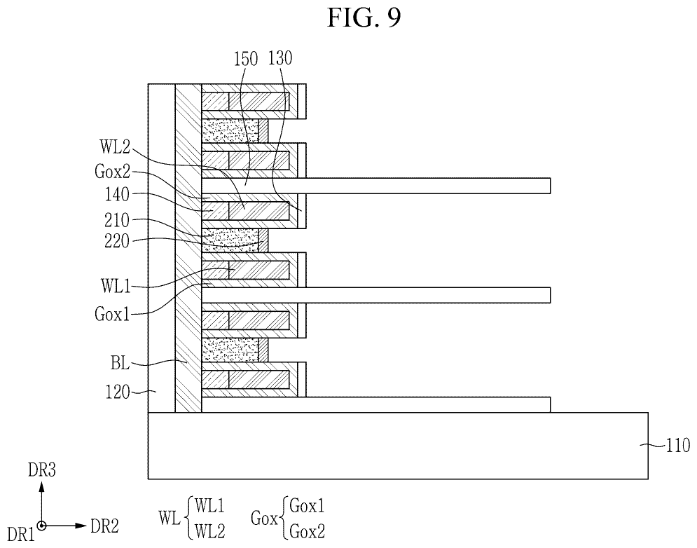

Referring to FIG. 9, the metal layer 215 may be removed. For example, the metal layer 215 may selectively etch the metal layer 215 by using an etchant having high etch selectivity.

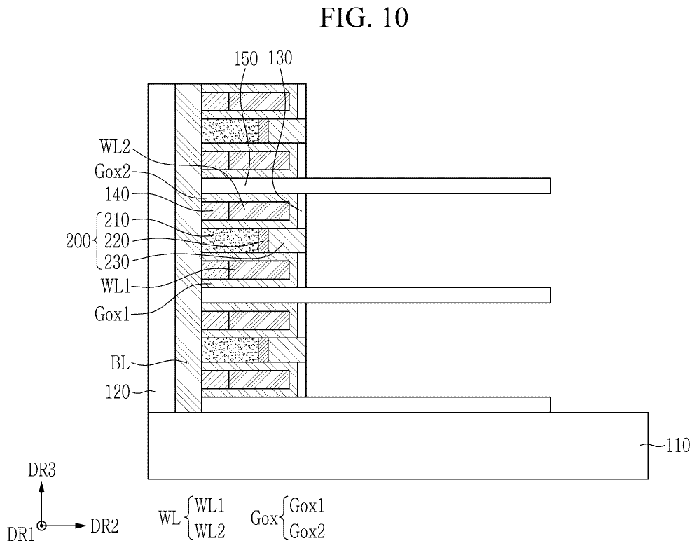

Referring to FIG. 10, a second portion 230 including an oxide semiconductor material may be formed. For example, the oxide semiconductor material layer may be deposited, and the oxide semiconductor material layer may be etched until the etch stopping layer 130 is exposed, to thus form a second portion 230. The oxide semiconductor material layer may be deposited, for example, by a physical vapor deposition (PVD) or chemical vapor deposition (CVD) process, but example embodiments are not limited thereto.

According to various example embodiments, the oxide semiconductor material may include a material having a high composition ratio of indium. The oxide semiconductor material may include, for example, an indium gallium zinc oxide (IGZO), an In₂O₃, an indium tin oxide (ITO), an indium gallium oxide (IGO), or an indium tin gallium oxide (ITGO), but example embodiments are not limited thereto.

One of the surfaces of the second portion 230 facing each other in the second direction DR2 may contact the third portion 220. The interface of the second portion 230 and the third portion 220 may be disposed between the extending lines of the surfaces of the first word line WL1 and the second word line WL2 facing each other in the second direction DR2. For example, the first word line WL1 may include a first surface and a second surface facing each other in the second direction DR2, and the second word line WL2 may include a third surface and a fourth surface facing each other in the second direction DR2. The interface of the second portion 230 and the third portion 220 may be disposed between the extending line of the first surface and the third surface and the extending line of the second surface and the fourth surface.

According to various example embodiments, at least a portion of the second portion 230 may overlap the first word line WL1 and the second word line WL2 in the third direction DR3.

According to various example embodiments, the semiconductor pattern 200 including a first portion 210 including polysilicon, a second portion 230 including an oxide semiconductor material, and a third portion 220 including a metal silicide material between the first portion 210 and the second portion 230 may be formed between the first word line WL1 and the second word line WL2. According to various example embodiments, the semiconductor pattern 200 includes the third portion 220, thereby limiting and/or preventing the first portion 210 from being oxidized to generate a SiO₂ in the process for forming the second portion 230 of FIG. 10.

According to various example embodiments, the surface of the second portion 230 exposed in the second direction DR2 and the surface of the etch stopping layer 130 exposed in the second direction DR2 may be disposed in a line, but are not limited thereto. For example, when etching the oxide semiconductor material layer, the etch stopping layer 130 may be exposed and may then be further etched. By this, the surface of the second portion 230 exposed in the second direction DR2 may disposed nearer the bit line BL than the exposed surface of the etch stopping layer 130.

According to several example embodiments, an anti-oxidation layer 180 of FIG. 3 may be additionally formed. For example, the anti-oxidation layer may be conformally formed to have the thickness of equal to or less than about 1 nm. The anti-oxidation layer may be formed to conformally cover the second portion 230 of the semiconductor patterns 200, the etch stopping layer 130, and exposed surfaces of the second interlayer insulating layers 150.

The anti-oxidation layer may, for example, include a silicon oxide, a silicon nitride, a silicon carbide, a silicon oxynitride, and a silicon carbonitride, but example embodiments are not limited thereto.

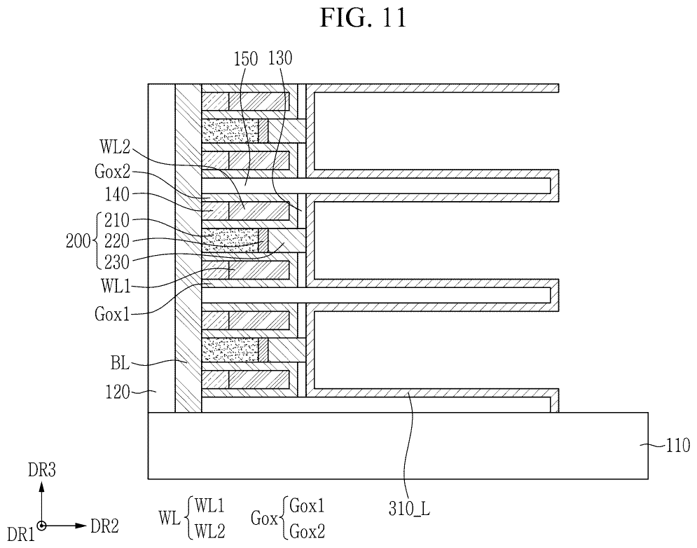

When processes to be described are performed after the anti-oxidation layer is additionally formed, a semiconductor device 101 according to various example embodiments of FIG. 3 may be formed. In this case, a first electrode material layer 310_L to be described with reference to FIG. 11 may be formed on the anti-oxidation layer.

According to several example embodiments, a conductive layer 190 of FIG. 4 may be additionally formed. For example, the conductive layer 190 may be conformally formed to cover the second portion 230 of the semiconductor patterns 200, the etch stopping layer 130, and the exposed surfaces of the second interlayer insulating layers 150. The conductive layer 190 may, for example, include a metal nitride such as a titanium nitride (TiN), a tungsten nitride (WN), or a tungsten carbonitride (WCN), or a metallic material such as cobalt (Co), but example embodiments are not limited thereto.

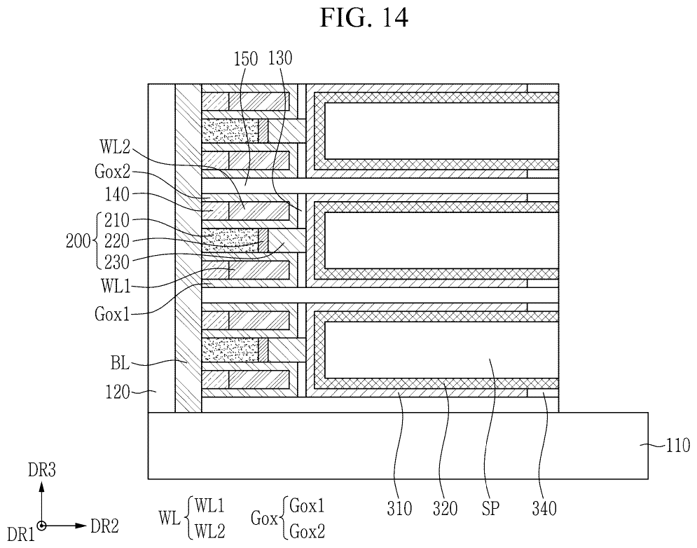

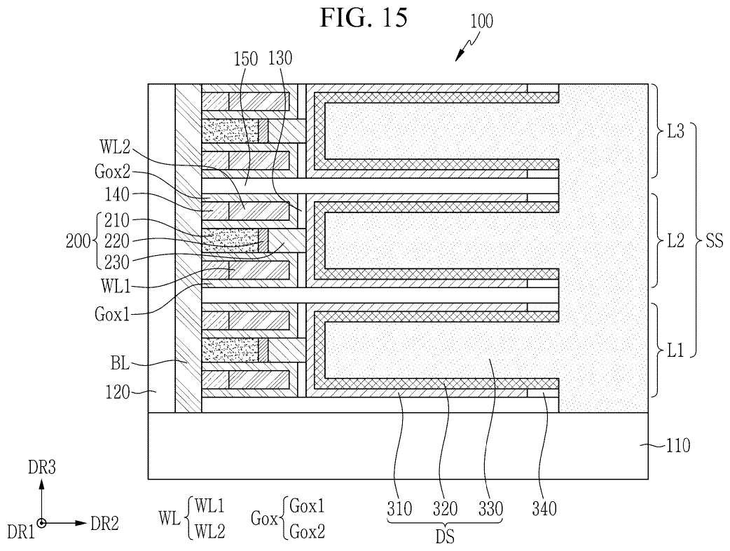

When processes to be described are performed after the conductive layer 190 is additionally formed, a semiconductor device 102 according to various example embodiments of FIG. 4 may be formed. In this case, the first electrode material layer 310_L to be described with reference to FIG. 11 may be formed on the conductive layer 190. When an insulating pattern 340 to be described with reference to FIG. 14 is, a portion of the conductive layer 190 in addition to the first electrode 310 may be etched. The insulating pattern 340 may cover surfaces that are etched and exposed portions of the conductive layer 190 and the first electrode 310. Referring to FIG. 15, the insulating pattern 340 may be disposed between the conductive layer 190 and the second electrode 330 and between the first electrode 310 and the second electrode 330.

Referring to FIG. 11, a first electrode material layer 310_L may be formed. For example, the first electrode material layer 310_L may be deposited by an ALD process, but example embodiments are not limited thereto.

According to various example embodiments, the first electrode material layer 310_L may conformally cover the second portion 230 of the semiconductor patterns 200, the etch stopping layer 130, and the exposed surfaces of the second interlayer insulating layer 150.

The first electrode material layer 310_L may, for example, include at least one of metallic materials such as titanium, tantalum, tungsten, copper, or aluminum, conductive metal nitrides such as a titanium nitride or a tantalum nitride, and doped semiconductor materials such as doped silicon or doped germanium. However, example embodiments are not limited thereto.

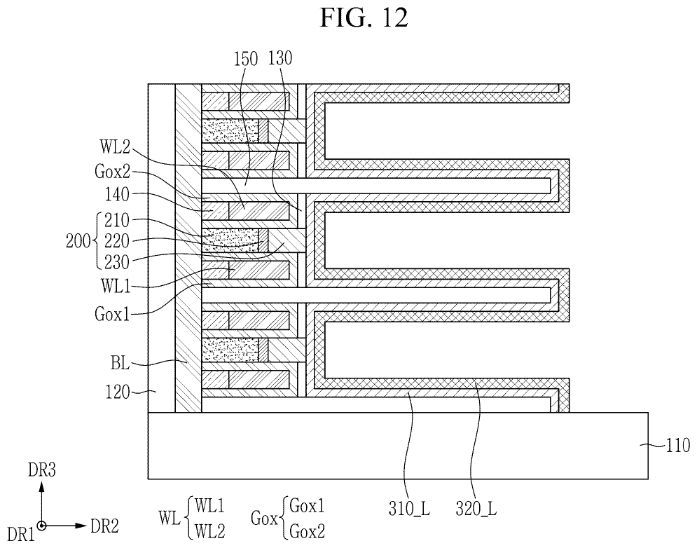

Referring to FIG. 12, a dielectric layer material layer 320_L may be formed. For example, the dielectric layer material layer 320_L may be deposited by the ALD process, but example embodiments are not limited thereto.

According to various example embodiments, the dielectric layer material layer 320_L may conformally cover the exposed surface of the first electrode material layer 310_L.

The dielectric layer material layer 320_L may, for example, include at least one of a dielectric material, a ferromagnetic material, and an antiferromagnetic material. However, example embodiments are not limited thereto. The dielectric material may include a high dielectric constant material, for example, it may include a hafnium oxide, a hafnium silicon oxide, a lanthanum oxide, a zirconium oxide, a zirconium silicon oxide, a tantalum oxide, a titanium oxide, a barium strontium titanium oxide, a barium titanium oxide, a strontium titanium oxide, a lithium oxide, an aluminum oxide, a lead scandium tantalum oxide, a lead zinc niobate, or combinations thereof. However, example embodiments are not limited thereto.

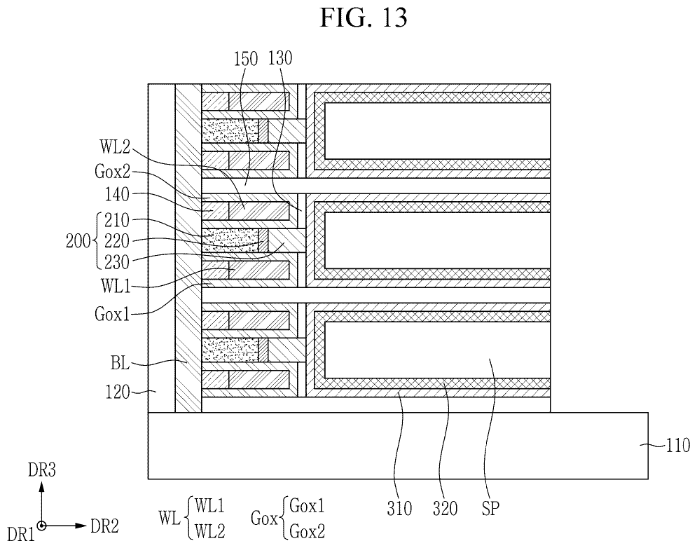

Referring to FIG. 13, a space that remains empty when the dielectric layer material layer 320_L is formed may be filled with a sacrificial layer material, and a trench for separating the first electrodes 310 may be formed. For example, a trench penetrating the second interlayer insulating layers 150, the first electrode material layer 310_L, the dielectric layer material layer 320_L, and the sacrificial layer material layer in the third direction DR3 may be formed.

As the trench is formed, the first electrode material layer 310_L, the dielectric layer material layer 320_L, and the sacrificial layer material layer connected along the lateral surface of the second interlayer insulating layer 150 may be respectively cut. A first electrode 310, a dielectric layer 320, and a sacrificial layer pattern (SP) may be formed between the adjacent second interlayer insulating layers 150.

According to various example embodiments, the first electrode 310 may include a vertical portion extending in the third direction DR3 and a pair of horizontal portions extending in the second direction DR2. The horizontal portion of the first electrode 310 may extend in the second direction DR2 to be distant from the bit line BL from the vertical portion of the first electrode 310. The pair of horizontal portions of the first electrode 310 may be spaced and disposed in the third direction DR3. The first electrode 310 may have a cylindrical form extending in the second direction DR2.

According to various example embodiments, the dielectric layer 320 may have a shape of covering an interior wall of the cylindrical first electrode 310. The sacrificial layer pattern SP may fill the internal space of the cylindrical first electrode 310, that remains when the dielectric layer 320 is formed. The sacrificial layer pattern SP may be surrounded by the dielectric layer 320.

Referring to FIG. 14, a portion of the first electrode 310 may be etched, and an insulating pattern 340 may be formed on the etched portion.

For example, the first electrode 310 exposed by the trench formed in FIG. 13 may be selectively etched. As a portion of the first electrode 310 is removed, a recess including the second interlayer insulating layer 150 and the dielectric layer 320 as sidewalls and the first electrode 310 as a bottom surface may be formed. An insulating pattern 340 may be formed in the recess.

The insulating pattern 340 may, for example, include at least one of a silicon nitride, a silicon oxidation nitride, a carbon-contained silicon oxide, a carbon-contained silicon nitride, and a carbon-contained silicon oxidation nitride.

Referring to FIG. 15, the sacrificial layer pattern SP may be removed, and a second electrode 330 may be formed. The sacrificial layer pattern SP may be removed by an etching process. When the sacrificial layer pattern SP is removed, the second electrode 330 may be deposited. The second electrode 330 may be formed by, for example, a PVD or CVD process, but example embodiments are not limited thereto.

second electrode 330 may, for example, include at least one of metallic materials such as titanium, tantalum, tungsten, copper, or aluminum, conductive metal nitrides such as titanium nitride or tantalum nitride, and doped semiconductor materials such as doped silicon or doped germanium. However, example embodiments are not limited thereto.

The second electrode 330 may, in replacement of the sacrificial layer pattern SP, fill the internal space of the cylindrical first electrode 310. The second electrode 330 may be inserted into the internal space of the cylindrical first electrode 310. The second electrode 330 may be surrounded by the dielectric layer 320. A portion of the second electrode 330 surrounded by the dielectric layer 320 may extend in the second direction DR2.

The second electrode 330 may cover the lateral surface of the dielectric layer 320, the lateral surface of the insulating pattern 340, and the lateral surface of the second interlayer insulating layer 150 and may extend in the third direction DR3.

According to various example embodiments, the first electrode 310, the portion of the second electrode 330 spaced from the first electrode 310, and the dielectric layer 320 disposed between the first electrode 310 and the second electrode 330 may configure a data storage pattern DS. The data storage pattern DS may be electrically connected to the semiconductor pattern 200 as the first electrode 310 contacts the second portion 230 of the semiconductor pattern 200.

According to various example embodiments, the semiconductor device 100 may include a stacking structure body SS in which the memory cells are stacked in the third direction DR3. For example, the stacking structure body SS may include a first layer L1, a second layer L2, and a third layer L3, which is not limited thereto, and may include a greater number of layers. For example, the second electrodes 330 of the data storage patterns DS respectively included in the first layer L1, the second layer L2, and the third layer L3 may be connected in the third direction DR3. The second electrode 330 may be spaced from the first electrode 310 of each layer by the dielectric layer 320 and the insulating pattern 340. The dielectric layer 320 and the insulating pattern 340 may insulate the second electrode 330 from the first electrode 310 of each layer.

While this disclosure has been described in connection with what is presently considered to be practical example embodiments, it is to be understood that the disclosure is not limited to the disclosed example embodiments, but, on the contrary, is intended to cover various modifications and equivalent arrangements included within the spirit and scope of the appended claims.

What is claimed is:

1. A semiconductor device comprising:
a substrate;
a bit line extending in a vertical direction, the vertical direction being perpendicular to an upper surface of the substrate;
semiconductor patterns having first ends connected to the bit line and spaced apart in the vertical direction;
a pair of word lines above and below respective semiconductor patterns; and
data storage patterns connected to second ends of respective semiconductor patterns,
wherein each of the semiconductor patterns include
a first portion connected to the bit line and including polysilicon,
a second portion connected to each of the data storage patterns and including an oxide semiconductor material, and
a third portion between the first portion and the second portion and including a metal silicide material.

2. The semiconductor device of claim 1, wherein
at least a portion of the second portion of the semiconductor patterns overlap the pair of word lines in the vertical direction.

3. The semiconductor device of claim 1, wherein
the pair of word lines entirely overlapping the third portion in the vertical direction.

4. The semiconductor device of claim 1, wherein
a region of the first portion near the third portion includes n-type impurities.

5. The semiconductor device of claim 1, wherein
the oxide semiconductor material includes indium gallium zinc oxide (IGZO), In₂O₃, indium tin oxide (ITO), indium gallium oxide (IGO), or indium tin gallium oxide (ITGO).

6. The semiconductor device of claim 1, further comprising
an anti-oxidation layer between each of the semiconductor patterns and each of the data storage patterns,
wherein the anti-oxidation layer has a thickness equal to or less than 1 nm.

7. The semiconductor device of claim 1, wherein
each of the data storage patterns include
a first electrode including a vertical portion extending in the vertical direction and a pair of horizontal portions extending in a horizontal direction, the horizontal direction being parallel to the upper surface of the substrate,
a second electrode spaced apart from the first electrode; and
a dielectric layer between the first electrode and the second electrode.

8. The semiconductor device of claim 7, further comprising
a conductive layer between each of the semiconductor patterns and each of the data storage patterns and surrounding the first electrode, and
an insulating pattern between the conductive layer and the second electrode and between the first electrode and the second electrode.

9. The semiconductor device of claim 7, wherein
the dielectric layer includes at least one of a dielectric material, a ferromagnetic material, or an antiferromagnetic material.

10. A semiconductor device comprising:
a substrate;
a bit line extending in a vertical direction, the vertical direction being perpendicular to an upper surface of the substrate;
semiconductor patterns having a first end connected to the bit line and spaced apart in the vertical direction;
a pair of word lines above and below respective semiconductor patterns and extending in a first direction, the first direction being parallel to the upper surface the substrate; and
data storage patterns connected to second ends of respective semiconductor patterns,
wherein each of the semiconductor patterns include
a first portion connected to the bit line and including polysilicon,
a second portion connected to the data storage pattern and including an oxide semiconductor material, and
a third portion between the first portion and the second portion and including a metal silicide material, and
an interface between the second portion and the third portion is between facing surfaces of the pair of word lines.

11. The semiconductor device of claim 10, wherein
the third portion is between facing surfaces of the pair of word lines.

12. The semiconductor device of claim 10, wherein
an interface between each of the second portions and the data storage patterns is further apart from the bit line than the surfaces of the word lines facing each other in the vertical direction.

13. The semiconductor device of claim 10, further comprising
an anti-oxidation layer between each of the second portions and the data storage patterns,
wherein the anti-oxidation layer has a conformal shape and a thickness equal to or less than 1 nm.

14. The semiconductor device of claim 10, further comprising
a conductive layer between each of the second portion and the data storage patterns,
wherein the conductive layer includes a vertical portion extending in the vertical direction and a pair of horizontal portions extending in a second direction, the second direction being parallel to the upper surface of the substrate and perpendicular to the first direction.

15. A semiconductor device comprising:
a substrate;
a bit line extending in a vertical direction, the vertical direction being perpendicular to an upper surface of the substrate;
semiconductor patterns having first ends connected to the bit line and spaced apart in the vertical direction;
a pair of word lines above and below respective semiconductor patterns and extending in a first direction that is parallel to the upper surface of the substrate; and
data storage patterns connected to second ends of respective semiconductor patterns,
wherein each of the semiconductor patterns include
a first portion connected to the bit line and including polysilicon,
a second portion connected to the data storage pattern and including an oxide semiconductor material, and
a third portion between the first portion and the second portion and including a metal silicide material, and
the first portion, the third portion, and the second portion are sequentially arranged in a second direction between the bit line and the data storage pattern, the second direction being parallel to the upper surface of the substrate and perpendicular to the first direction.

16. The semiconductor device of claim 15, wherein
a portion of the first portion, at least a portion of the second portion, and the third portion overlap the pair of word lines in the vertical direction.

17. The semiconductor device of claim 16, wherein
a length of the first portion in the second direction, overlapping the pair of word lines is greater than a length of the second portion in the second direction, overlapping the pair of word lines.

18. The semiconductor device of claim 16, further comprising
a pair of gate insulating layers for spacing the semiconductor patterns from the pair of word lines, and
a pair of etch stopping layers between the pair of gate insulating layers and the data storage patterns.

19. The semiconductor device of claim 18, wherein
an interface of the second portion and the data storage pattern is between interfaces of the pair of etch stopping layers and the data storage patterns in the vertical direction.

20. The semiconductor device of claim 19, wherein
the interface of the second portion and the data storage pattern and the interface of the etch stopping layers and the data storage patterns are in a line.
